(19) United States
(12) Patent Application Publication
(10) Pub. No.: US 2007/0194430 A1
(43) Pub. Date: Aug. 23, 2007

(54) Substrate of chip package and chip package structure thereof

(75) Inventors: Chi Chih Lin, Pingihen City (TW); Bo Sun, Pingihen City (TW); Hung Jen Wang, Gueishan Township (TW)

Correspondence Address: ABELMAN, FRAYNE & SCHWAB, 666 THIRD AVENUE, 10TH FLOOR, NEW YORK, NY, 10017, US

(73) Assignee: Taiwan Solutions Systems Corp.

(21) Appl. No.: 11/699,655

(22) Filed: Jan. 29, 2007

(30) Foreign Application Priority Data
Feb. 17, 2006 (TW) 95105440

(51) Int. Cl. H01L 23/48

(52) U.S. Cl. 257/690

(57) ABSTRACT

A substrate of chip package and the chip package structure thereof centralizes the bonding area under a chip carrier area and protrudes the bonding area from the chip carrier area to a chip package so as to increase the reliability of bump type surface mount technology during the second-level electronic assembly. Furthermore, the carrier for produce the substrate is recyclable during the chip package procedure so as to reduce the production cost.

### BACKGROUND OF THE INVENTION

1. Field of the Invention

The present invention relates to a semiconductor package structure and, more especially, to a chip package structure which centralizes the surface mounting technology (SMT) bonding area under the chip carrier area so as to reduce the scale of the chip package.

2. Description of the Prior Art

The chip package is used to protect the integrated chip (IC) component and to build up the organization of the chip, and the purpose of the chip package is to provide the chip with the substation ability and the organization protection ability, to prevent the chip from the destruction caused by the external force during the pick and place process and any other physical property, or the erosion from the chemical property, to assure the energy transmission path and the signal distribution of the chip, to avoid the system operation impact caused by the signal delay, and to provide the dissipate path. Since the various kinds of electronic products are mass produced and the outward appearance of these electronic products are becoming smaller and thinner, for example, the network communication related products (mobile phone, PHS, GPS . . . etc), the message related products (PDA, portable IA, electronic book . . . etc), the consumer electronics (electronic dictionary, hand-held videogame, card reader, stock PDA . . . etc), and even more the instrument for medical use or automobile electronic industry. Thus, how to reduce the size of the chip package is the tendency within the semiconductor package field to satisfy the compact trend of the electronic product.

For the chip package technology, every die, which formed by dicing the wafer, is fastened upon the surface of a carrier by wire bonding or by flip-chip bonding methodology, wherein the carrier is a lead frame or a substrate. And the active surface of the chip includes a plurality of solder pads to electrically connect the external electronic apparatus and the chip through the transmission path and the terminal of the carrier. After that, a molding compound is used to cover the chip and the conductive wire to accomplish a chip package structure.

As shown in FIG. 1, it is a cross-sectional diagram of a conventional chip package structure. A chip carrier, such as a lead frame, is a metal patterned circuit 110 formed by etching a photoresist-coated metallic board in a lithography process, wherein the chip carrier further includes a metal surface layer, such as a tinning, a silver, or a nickel gold (not shown), is formed by a surface treatment on the surface of the metal patterned circuit 110. A die paddle 120 is configured on the metal patterned circuit 110, and an adhesive layer 130 and a chip 140 are stacked sequentially upon the die paddle 120. The chip 140 electrically connects to the metal patterned circuit 110 via a plurality of conductive wires 142. After that, a molding compound 144 covers the chip 140, those conductive wires 142 and the metal patterned circuit 110. The surface of the metal patterned circuit 110 exposed to the molding compound 144 is processed externally to form a metal surface layer 150, such as a tin, a silver, or a nickel gold layer. Accordingly, for the top view of the chip package structure, the metal patterned circuit is exposed to the die paddle and the chip package includes an interval between the die paddle and the conductive wires.

Although the conventional chip package, which utilizes a metal lead frame to assemble the chip and to bond the wire, has the advantages of low cost, efficient heat dissipation and scale reduction for a multi-layer laminate utilizing a tin solder ball array arranged on the bottom of the multi-layer laminate substrate to increase the amount of the lead in the same area, it still has the limits in the scale reduction due to the material composition for the current electronic components, which have been developed with a smaller size and a higher density.

### SUMMARY OF THE INVENTION

According to the issue mentioned previously, one of objects of this invention is to provide a substrate of a chip package structure. The substrate centralizes the bonding area under the chip carrier area to dramatically reduce the scale of the package and to approach the scale to the scale of the wafer level package. The substrate shortens the distance between the electrical connection points of the chip and the solder pad so as to minimize the chip package.

Another object of this invention is to provide a substrate of chip package structure. The manufacturing procedure of the substrate is as the same as the current manufacturing procedure of the laminate substrate so as to increase the production output per procedure and to drop the production cost.

Another object of this invention is to provide a substrate of chip package structure. The substrate centralizes the bonding area under the chip carrier area and to protrude the bonding area from the chip carrier area to the chip package so as to increase the reliability of bump type surface mount technology during second level electronic assembly.

Another object of this invention is to provide a substrate of chip package structure. In manufacturing the chip package, the carrier making the substrate of the chip package is recyclable so as to dramatically reduce the production cost.

Accordingly, one embodiment of the present invention provides a substrate of a chip package, it includes a plurality of connection pads separated from each other with an interval; an insulation layer, wherein a lower surface of the insulation layer contacts but exposes part of the upper surface of the connection pads to form at least one cavity; and a conductive solder pad is arranged on the exposed upper surface of the connection pads, wherein an area of the upper surface of the insulation layer between the conductive solder pad is defined as a chip carrier area, wherein the interval between connection pads is smaller than a size of the chip carrier area.

Accordingly, one embodiment of the present invention provides a chip package, it includes a plurality of connection pads separated from each other with an interval; an insulation layer, wherein the lower surface of the insulation layer contacts but exposes part of the upper surface of connection pads to form at least one cavity; a conductive solder pad is arranged on the exposed upper surface of the connection pads, wherein an area of the upper surface of the insulation layer between the conductive solder pad is defined as a chip carrier area, wherein the interval between connection pads is smaller than the size of the chip carrier area; a chip is arranged on the chip carrier area; a conductive connection structure is used to electrically connect the chip and the conductive solders pad; and a molding compound, is used to cover the chip and the conductive connection structure.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a cross-sectional diagram of a conventional chip package structure;

FIG. 2A, FIG. 2B, FIG. 2C, and FIG. 2D are cross-sectional diagrams of the substrate in accordance with an embodiment of the present invention;

FIG. 3A, FIG. 3B, FIG. 3C, and FIG. 3D are cross-sectional diagrams of the substrate in accordance with another embodiment of the present invention;

FIG. 4 is a cross-sectional diagram of the chip package structure in accordance with FIG. 3A;

FIG. 5 is a cross-sectional diagram of the CMOS sensor chip package in accordance with FIG. 3A;

FIG. 6, FIG. 7, and FIG. 8 are cross-sectional diagrams of the flip chip package structure in accordance with FIG. 3B; and

FIG. 9A, FIG. 9B, FIG. 9C, FIG. 9D, and FIG. 9E are cross-sectional diagrams of the chip package of the package procedure in accordance with an embodiment of the present invention.

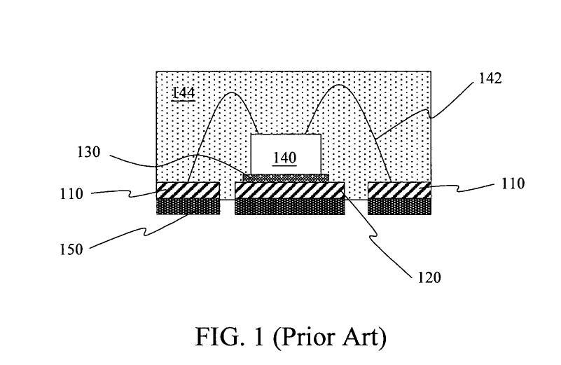

### DETAILED DESCRIPTION OF THE INVENTION

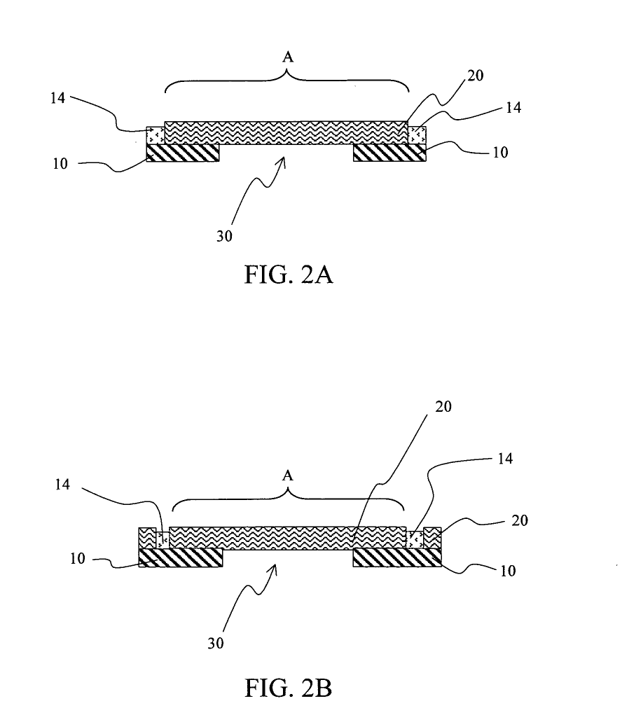

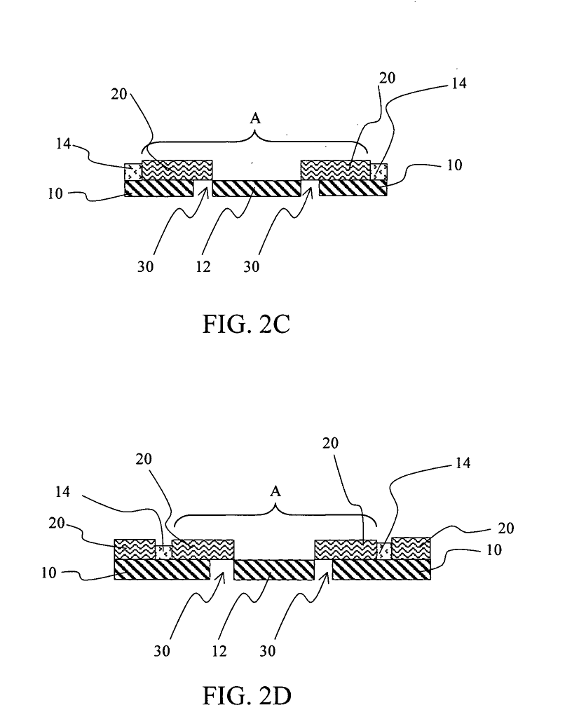

Shown in FIG. 2A, it is a cross-sectional diagram of the substrate in accordance with an embodiment of the present invention. In the preferred embodiment, the substrate of the chip package includes: a plurality of connection pads 10 separated from each other with an interval. The lower surface of an insulation layer 20 contacts but exposes part of the upper surface of the connection pads 10 which is positioned on two sides of the insulation layer 20. The insulation layer 20 and the neighboring connection pads 10 define a cavity 30. A conductive solder pad 14 is arranged on the exposed upper surface of the connection pads 10 as a plurality of electrical connection points. Wherein an area of the upper surface of the insulation layer 20 between the conductive solder pad 14 is defined as a chip carrier area A, wherein the interval between connection pads 10 is smaller than the size of the chip carrier area A. In the preferred embodiment, which shown in FIG. 2B, the location of the upper surface of the connection pads 10 exposed by the insulation layer 20 is moved inward to the insides of the insulation layer 20, said, the location of the conductive solder pad 14 is moved inward to the insides of the connection pad 10 and the conductive solder pad 14 is surrounded by the insulation layer 20. Another embodiment shown in FIG. 2C different from one in FIG. 2A, a die paddle 12 and the connection pads 10 are simultaneously formed in which the size of the die paddle 12 is smaller than the one of an incoming loaded chip and the part of the die paddle 12 is exposed to the insulation layer 20. In this preferred embodiment, the insulation layer 20, the connection pads 10 and the die paddle 12 define a plurality of cavities 30. Comparing with the embodiment shown in FIG. 2C, for an embodiment shown in FIG. 2D, the conductive solder pad 14 is moved inward to the insides of the connection pad 10. For all the abovementioned embodiments, the connection pads 10 which mentioned previously are metal leads.

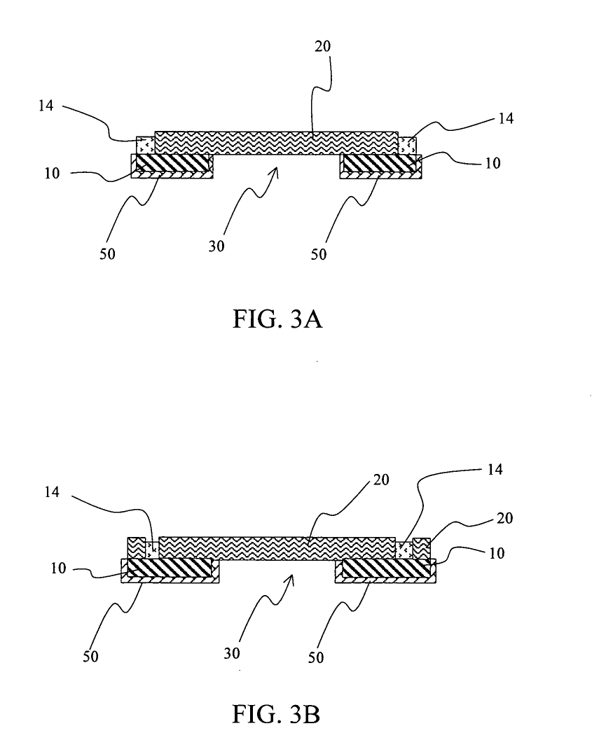

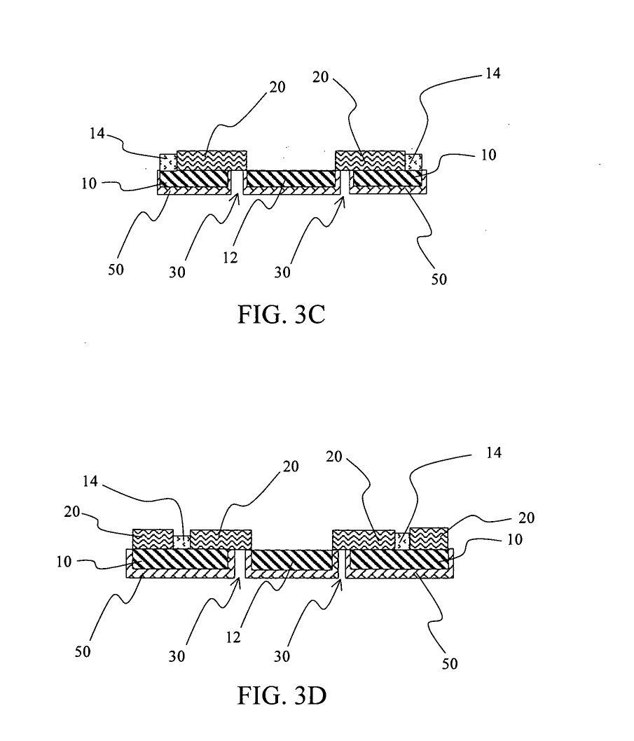

Continuously, for an embodiment shown in FIG. 3A, the difference between embodiments shown in FIG. 3A and FIG. 2A is that a metal layer 50, for example a tinning, a silver, or a nickel gold, surrounding lower surfaces of the connection pads 10, which do not contact with the insulation layer 20 and the connective solder pad 14, forms the electrical connection points to transmit the signal to the external circuit. Comparing with the embodiment shown in FIG. 3A, for another embodiment shown in FIG. 3B, the conductive solder pad 14 is moved inward to the insides of the connection pad 10. For an embodiment shown in FIG. 3C, the difference between embodiments shown in FIG. 3C and FIG. 2C is that a metal layer 50 surrounding the lower surfaces of the connection pad 10, which do not contact with the insulation layer 20 and the connective solder pad 14, forms the electrical connection points to transmit the signal to the external circuit. Comparing with the embodiment shown in FIG. 3C, for an embodiment shown in FIG. 3D, the conductive solder pad 14 is moved inward to the insides of the connection pad 10.

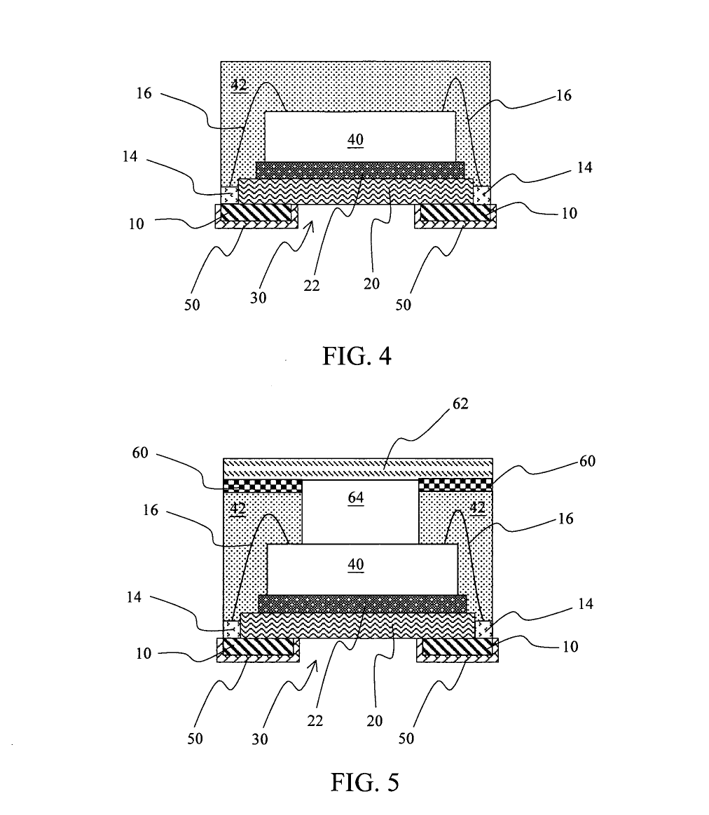

For an embodiment shown in FIG. 4, it is a cross-sectional diagram of the chip package structure in accordance with FIG. 3A. As shown in FIG. 4, except for the substrate shown in FIG. 3A, a chip 40 is arranged on the chip carrier area A of the insulation layer 20, a conductive connection structure, for example a conductive wire 16, is used to electrically connected with the chip 40 and the conductive solder pad 14, and, moreover, an adhesive layer 22, for example a conductive adhesive or an insulation adhesive, wherein the adhesive layer 22 is arranged between the chip 40 and the insulation layer 20. Besides, a molding compound 42 covers the chip 40 and the conductive connection structure.

Continuously shown in FIG. 5 is a cross-sectional diagram of the CMOS sensor chip package in accordance with FIG. 3A. As shown in FIG. 5, except for the structure shown in FIG. 4, an adhesive layer 60 is configured between the molding compound 42 and an upper substrate 62, wherein the upper substrate 62 is a glass, a ceramic, or a metal. Depending on the requirement of the CMOS sensor chip, the molding compound 42 and the adhesive layer 60 above the chip can be removed in order to form a cavity 64. Accordingly, due to the distance between each connection pad 10 is shorter than the length of the chip carrier area, so that the relatively location of the chip 40 and the connection pad 10 are partly overlap. Continuously, in the preferred embodiment, the CMOS sensor chip package further includes a colloid layer (not shown) positioned on the upper surface of the chip 40, for example a pressure sensor chip. It is understood that the substrate used in aforementioned embodiments can be the substrate without the die paddle shown in FIG. 2A and FIG. 2B, or the substrate with die paddle shown in FIG. 3C and FIG. 3D.

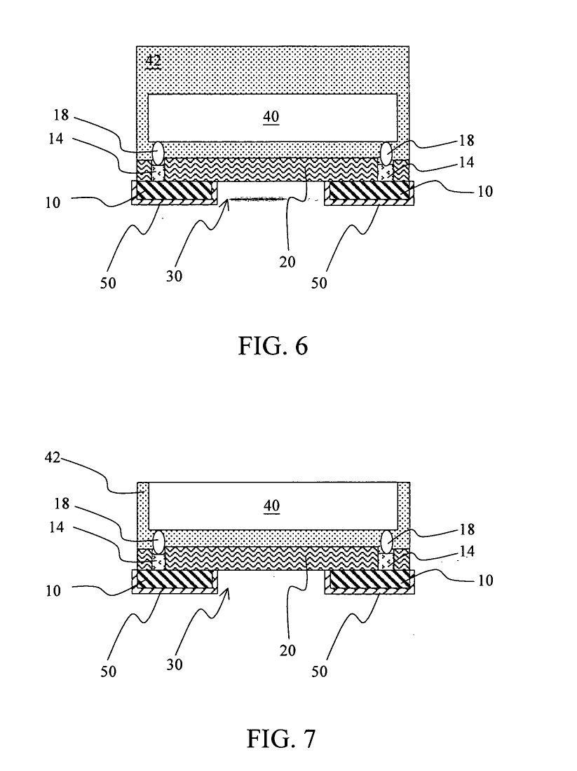

Shown in FIG. 6, FIG. 7, and FIG. 8, they are cross-sectional diagrams of the flip chip package structure in accordance with FIG. 3B. Shown in FIG. 6, no adhesive layer is needed to connect the chip 40 and the insulation layer 20, the chip 40 just needs a conductive ball, for example a solder ball, to fasten the chip 40 and electrically connect the chip 40 to the conductive solder pad 14. And covers all elements which mentioned previously with a molding compound 42. Shown in FIG. 7, the difference between FIG. 7 and FIG. 6 is that the molding compound 42 covers all the elements but exposes the upper surface of the chip 40. Shown in FIG. 8, the difference between FIG. 8 and FIG. 6 is that the present embodiment is utilizing a conductive bump 19, like a golden bump, to replace the conductive ball 18 which shown in FIG. 6. It is understood that the substrate used in aforementioned embodiments can be the substrate without the die paddle shown in FIG. 2A and FIG. 2B, or the substrate with die paddle shown in FIG. 3C and FIG. 3D.

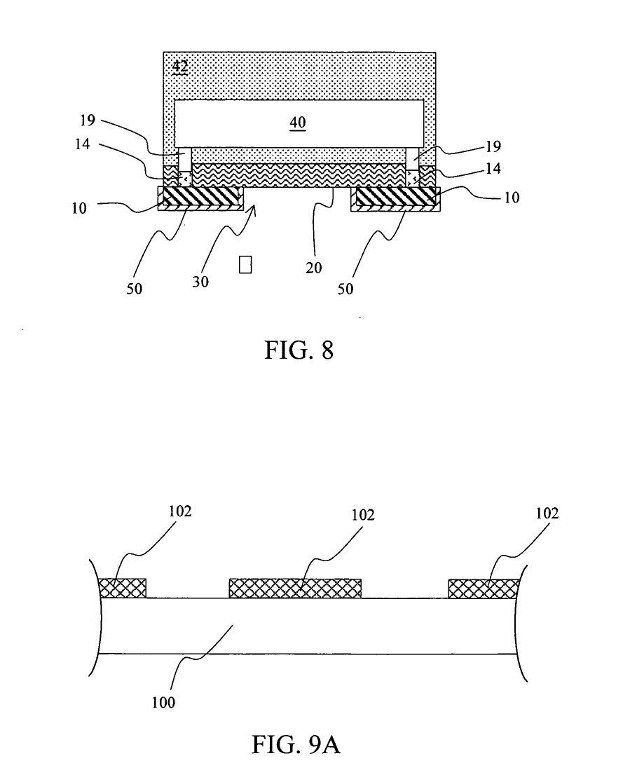

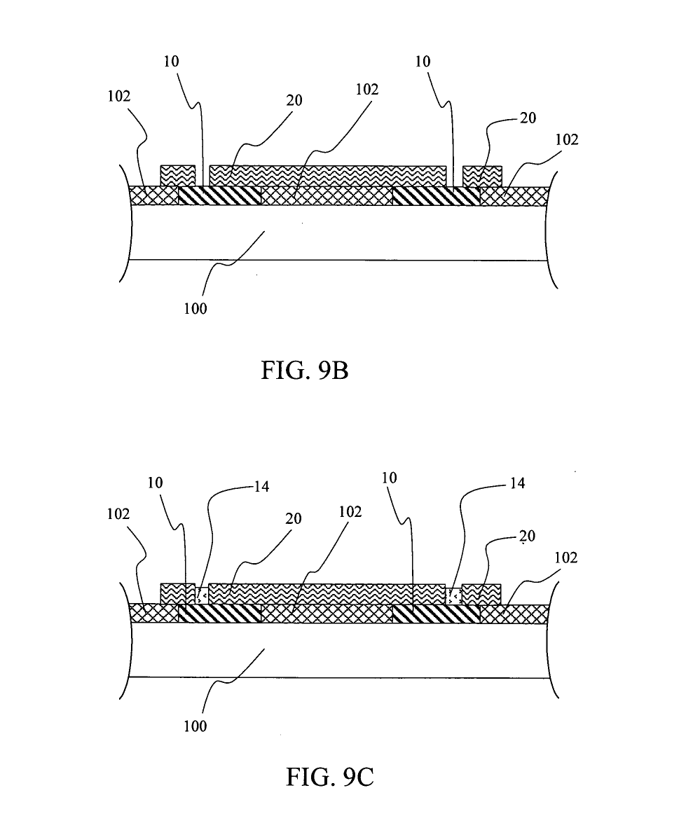

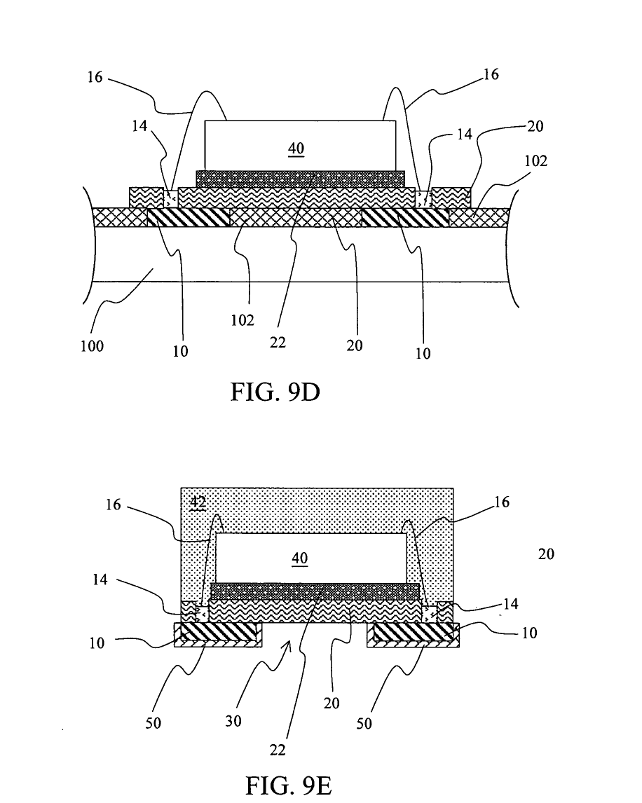

The cross-sectional diagrams FIG. 9A, FIG. 9B, FIG. 9C, FIG. 9D, and FIG. 9E are used to illustrate the manufacturing procedure of a substrate and a chip package in accordance with an embodiment of the present invention. As shown in FIG. 9A, first of all, the package procedure provides a carrier 100 and then forms a buffer 102 on the carrier 100, wherein the buffer 102 has a pattern on it. Next, shown in FIG. 9B, the package procedure forms a plurality of connection pads 10 within the pattern of the buffer 102, and to space these connection pads 10 separated from each other with an interval, wherein the interval between connection pads 10 is smaller than the size of the chip carrier area. Continuously, forms an insulation layer 20 on the buffer 102 and the connection pad 10, wherein the insulation layer 20 exposes part of the upper surface of the connection pad 10. Then, shown in FIG. 9C, the package procedure forms a conductive solder pad 14 on the exposed upper surface of the connection pad 10 so as to finish the substrate structure of the chip package which is shown in FIG. 2B. Next, shown in FIG. 9D, the package procedure places a chip 40 on the chip carrier area of the insulation layer 20 and forms an adhesive layer 22 between the chip 40 and the insulation layer 20. Then, the package procedure forms a conductive connection structure, like a conductive wire 16, to electrically connect the chip 40 and the conductive solder pad 14. Besides, shown in FIG. 9E, the package procedure utilizes a molding compound 42 to cover the chip 40 and the conductive connection structure. Next, the package procedure removes the carrier 100 and the buffer 102. After that, forms a metal layer 50, for example a tinning, a silver, or a nickel gold, to surround the surfaces of the connection pad 10 but the surface which contacts with the insulation layer 20 and conductive solder pad 14. Wherein the metal layer 50 is used to be an electrical connection point to transmit the signal to the outside of the chip package. It is understood that the substrate used in aforementioned embodiments can be the substrate without the die paddle shown in FIG. 2A and FIG. 2B, or the substrate with die paddle shown in FIG. 3C and FIG. 3D. There is only one thing need to be take care when forming the buffer 102 and the insulation layer 20 is that to change the pattern type depends on the chip package specification, such as the location of the conductive solder pad and the location of the die paddle. And, the material of the buffer 102 conjugates well with the carrier 100, the insulation layer 20 and the connection pad 10.

Accordingly, the buffer 102 is made of the Teflon, the resin, or the chromium. And, the buffer 102 is formed on the carrier 100 by using the pasting, the laminating, the printing, the spraying, the evaporating, the electroplating, the scribbling, or the electroless plating methodology. Thus, due to the protection of the buffer 102, the removed carrier 100 can be recycled to remanufacture the substrate of the chip package. Formally, the procedure of manufacturing the chip package, the carrier is disposable in the past, but in the present invention, the carrier is recyclable to dramatically reduce the production cost.

Accordingly, the substrate in accordance with the present embodiment, the bonding area is centralized under the chip carrier area to dramatically reduce the scale of the chip package and to approach the scale to the scale of the wafer level package, and the distance between the electrical connection point and the solder pad is shortened so as to minimize the chip package. Besides, the manufacturing procedure of the substrate is as the same as the current manufacturing procedure of the laminate substrate so as to increase the production output per procedure and to drop the production cost. Moreover, the bonding area under the chip carrier area is designed to protrude from the chip carrier area so as to increase the reliability of bump type surface mount technology during second level electronic assembly. Furthermore, in accordance with the present embodiment, the thickness of the substrate is thinner than that of the conventional lead frame and the conventional carrier, and, in procedure of manufacturing the chip package substrate and assembling the chip package, the carrier for producing the substrate is recyclable so as to dramatically reduce the production cost.

Although the present invention has been explained in relation to its preferred embodiment, it is to be understood that other modifications and variation can be made without departing the spirit and scope of the invention as hereafter claimed.

What is claimed is:

1. A substrate of a chip package, comprising:
a plurality of connection pads separated from each other with an interval;
an insulation layer, wherein a lower surface of said insulation layer contacts but exposes part of an upper surface of said connection pads to form at least one cavity; and
a conductive solder pad arranged on said exposed upper surface of said connection pads, wherein an area of said upper surface of said insulation layer between said conductive solder pad is defined as a chip carrier area, wherein said interval between connection pads is smaller than a size of said chip carrier area.

2. A substrate of a chip package according to claim 1, further comprising a die paddle configured between said connection pads, wherein the size of said die paddle is smaller than the size of a chip.

3. A substrate of a chip package according to claim 2, wherein said insulation layer exposes an upper surface of said die paddle.

4. A substrate of a chip package according to claim 1, further comprising a metal layer configured on a lower surface of said connection pads.

5. A substrate of a chip package according to claim 1, wherein said connection pads are metal leads.

6. A chip package structure, comprising:
a plurality of connection pads separated from each other with an interval;
an insulation layer, wherein said insulation layer comprises a lower surface contacts with an upper surface of said connection pads and expose part of said upper surface of said connection pads, wherein said insulation layer and said connection pads form at least one cavity;
a conductive solder pad arranged on said exposed upper surface of said connection pads, wherein an area of said upper surface of said insulation layer between said conductive solder pad is defined as a chip carrier area, wherein said interval between connection pads is smaller than a size of said chip carrier area;
a chip arranged on said chip carrier area;
a conductive connection structure electrically connected said chip and said conductive pads; and
a molding compound covering said chip and said conductive connection structure.

7. A chip package structure according to claim 6, further comprising a die paddle configured between said connection pads, wherein the size of said die paddle is smaller than the size of said chip.

8. A chip package structure according to claim 7, wherein said insulation layer exposes an upper surface of said die paddle.

9. A chip package structure according to claim 6, further comprising a metal layer configured on a lower surface of said connection pads.

10. A chip package structure according to claim 6, wherein said connection pads are metal leads.

11. A chip package structure according to claim 6, further comprising an adhesive layer configured between said chip and said insulation layer.

12. A chip package structure according to claim 6, wherein said molding compound exposes an upper surface of said chip.

13. A chip package structure according to claim 12, further comprising an adhesive layer on said molding compound, and an upper substrate arranged on said adhesive layer and positioned on said upper surface of said chip.

14. A chip package structure according to claim 6, wherein said conductive connection structure is a conductive wire.

15. A chip package structure according to claim 6, wherein said conductive connection structure is a golden bump.

16. A chip package structure according to claim 6, wherein said conductive connection structure is a solder ball.
